(19) United States
(12) Patent Application Publication
(10) Pub. No.: US 2008/0203903 A1
(43) Pub. Date: Aug. 28, 2008

(54) Oled-Device With Pattered Light Emitting Layer Thickness

(75) Inventors: Margreet De Kok, Eindhoven (NL); Eric Alexander Meulenkamp, Eindhoven (NL)

Correspondence Address: PHILIPS INTELLECTUAL PROPERTY & STANDARDS, PO BOX 3001, BRIARCLIFF MANOR, NY, 10510-8001, US

(73) Assignee: KONINKLIJKE PHILIPS ELECTRONICS N.V., EINDHOVEN (NL)

(21) Appl. No.: 11/816,336

(22) PCT Filed: Feb. 8, 2006
(86) PCT No.: PCT/IB06/50407

§ 371 Date: Aug. 15, 2007

(30) Foreign Application Priority Data
Feb. 17, 2005 (EP) 05101173.2

(51) Int. Cl. H01L 27/32

(52) U.S. Cl. 313/504

(57) ABSTRACT

An organic light emitting diode device being patterned into a plurality of independently addressable domains (11, 12) is disclosed. The light emitting layer (4) is of a first thickness (41) in a first domain (11) of the device and of a second thickness (42) in a second domain (12) of the device, such that when a voltage, that is sufficient to cause light to emit from said first domain (11) and said second domain (12), is applied over said light emitting layer (4), light of a first color point is emitted by said first domain (11) of said device and light of a second color point is emitted by said second domain (12) of said device.

### TECHNICAL FIELD

The present invention relates to an organic light emitting diode device comprising a substrate supporting an anode, a cathode and a light emitting layer comprising at least one organic electroluminescent compound, said light emitting layer being sandwiched between said anode and said cathode, and said device being patterned into a plurality of independently addressable domains.

### TECHNICAL BACKGROUND

Organic based light emitting diodes (OLEDs), such as polymer OLEDs (polyLEDs), small-molecule OLEDs (smOLEDs) and light emitting electrochemical cells (LEEC) are proposed for several different lighting applications, such as for providing ambient light and as light sources in flat panel displays.

The technology of organic LEDs allows for the fabrication of for instance, thin, self-emissive displays, based on light emitting materials. These materials may be for example small-molecules, dendrimers, oligomers, and polymers.

Organic LEDs typically consist of a multi-layer structure, with one or more layers with electrical and/or optical functionality sandwiched between two conductive electrodes. Standard ITO may be used for the anode, and the cathode is specially designed to facilitate the electron injection. At least one of the layers is an active layer responsible for light emission. Other layers may be present to enhance the organic LED performance. For example, insertion of hole and/or electron injection and transport layer(s) is known to result in improved performance of several types of organic LEDs.

Thus, a typical OLED comprises two organic layers sandwiched between two conductive electrodes. Counting from the anode, the first of the organic layers is responsible for hole transport and the second layer is responsible for the light generation. Electrons injected by the cathode and holes injected from the anode recombine in the light emitting layer, resulting in an exciton that decays radiatively in producing a photon. The color of the emitted light may thus be tuned by varying the band-gap of the emissive material used.

For lighting applications, the color-tunability, i.e. the ability to tune the color point (temperature) to a desired value, of a white light source is a very important feature. The wider the color points may be chosen by the consumer, the better equipped the light source is. “Emotional lighting” in which atmosphere may be created by a different color temperature of the artificial light is regarded as an important feature for future light sources.

One common approach to obtain a color-tunable organic LED light source is to combine differently colored pixels into one device by pixelating different light emitting materials, as is usually done in a full-color display. However, such an approach requires the use of more than one light emitting material, and is as such cumbersome to manufacture.

A device that allows a user to choose the color temperature of light emitted by a polyLED, utilizing a single light emitting material, is described in U.S. Pat. No. 6,091,197, to Sun et al.

In this patent, Sun et al describe a color-tunable organic light emitting diode (RCOLED) including a high-reflection tunable membrane and a high-reflection dielectric mirror that form a resonant cavity. A white-light OLED is located in the resonant cavity. The high-reflection tunable membrane is moved to alter the resonant cavity length, and/or tilted/bowed to change the finesse of the resonant cavity. In this way, color, brightness and color saturation of the emitted light from the RCOLED may be tuned. This device is quite complicated to produce, and for color-tuning it requires mechanical influences on the device, e.g. by moving, tilting and/or bowing the reflection membrane.

Thus, there remains a need for color-tunable light emitting devices which obviate the need for several different light emitting materials, and which not require mechanical influences on the device for the color-tuning.

### SUMMARY OF THE INVENTION

One object of the present invention is to overcome the above-mentioned problems with prior art. The inventors have surprisingly found that the color point, e.g. as defined by a certain coordinate in for example a color rendering index diagram, of light emitted by an OLED-device depends on the thickness of the light emitting layer. By providing a patterned OLED-device having a light emitting layer, which is patterned in thickness into several domains, and which domains are driven individually, a color-tunable device is obtainable. A color-tunable device as used herein refers to a light emitting device, with a possibility of controlling the color point of emitted light, e.g. either automatically by a feedback system or manually by a user. Thus, in a first aspect, the invention provides a light emitting device based on OLED-technology, where different domains of the device emit light of different color points.

Such a device comprises a substrate supporting an anode, a cathode and a light emitting layer comprising an organic electroluminescent compound. The light emitting layer is arranged between the anode and the cathode, and the device is patterned into a plurality of independently addressable domains.

In a device of the present invention, the light emitting layer is of a first thickness in a first domain of the device and of a second thickness in a second domain. Due to this difference in thickness, light of a first color point is emitted by the first domain and light of a second color point is emitted by the second domain when a voltage, that is sufficient to cause light to emit from the first domain and second domain, is applied over said light emitting layer.

By driving these different domains of the device independently, the emission of light from the device may be tailored by mixing light from different domains of different color points to obtain a color variable light emitting device. As the material composition of the light emitting layer is at least essentially the same in the different domains of the device, a color-tunable device may thus be obtained by using only a single light emitting layer composition. The light emitting layer may comprise organic electroluminescent compounds (emitters), such as, for example small organic molecule emitters, oligomeric emitters, polymeric emitters or dendrimeric emitters.

The light emitting material may further comprise a blend or mixture of two or more different emitters, for example two emitters of different type and/or emitters that emit light of different colors. A device of the present invention may provide white light. Further, the first color point corresponding to a first domain of the device may represent a first white color point and a second color point corresponding to a second domain of the device may represent a second white color point. In embodiments of the present invention, the active layer may further comprise additional light emitting layers, which may or may not be patterned into different domains having different thicknesses. Such additional light emitting layers may be used in order to mix the color of the light emitted by the two or more light emitting layers to provide light of a desired color. Devices of the present invention may further comprise additional layers arranged between the anode and the cathode. Examples of such additional layers include a layer having hole transporting and injecting functionality arranged between the anode and the light emitting layer, and a layer having electron transporting and injecting functionality arranged between the light emitting layer and the cathode. Such hole or electron transport and injection layers may enhance the performance of the device according to the invention.

Light emitting devices according to the present invention may for example be used in different lighting systems, for example room lighting, stage lighting, and for backlight applications in display devices, such as LCD-displays.

### BRIEF DESCRIPTION OF THE DRAWINGS

The present invention will now be further described in the following description of preferred embodiments with reference to the drawings, in which:

FIG. 1 illustrates, in cross section, a light emitting device of the present invention with a patterned light emitting polymer layer.

FIG. 2 is a graph of the electroluminescence spectra of devices having an approximately 200 nm thick PEDOT-layer, and varying light emitting polymer layer thickness of 55 nm, 84 nm and 124 nm.

FIG. 3 is a color coordinate diagram of the spectra for the devices in FIG. 2.

FIG. 4 is a CIE color coordinate diagram for three different devices having an approximately 200 nm thick PEDOT-layer, and varying light emitting polymer layer thickness of 55 nm, 84 nm and 124 nm, driven at different voltages.

FIG. 5 is a graph of CIE-coordinates for three different devices of different LEP-thickness versus the luminance of the emitted light.

FIG. 6 is a CIE-color coordinate graph for three different devices of different LEP-thickness at 300 cd/m².

### DETAILED DESCRIPTION OF PREFERRED EMBODIMENTS

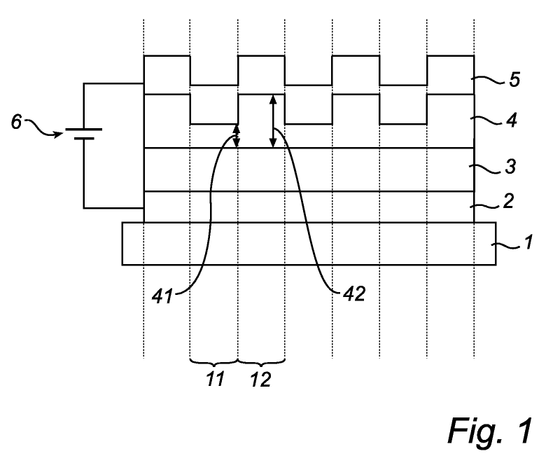

One preferred embodiment of a color-tunable OLED device according to the present invention is shown in FIG. 1 and comprises a substrate 1, an anode 2 arranged on the substrate 1, a hole transporting buffer layer 3 arranged on the anode 2, a light emitting polymer (LEP) layer 4 arranged on the hole transporting buffer layer 3 and a cathode 5 arranged on the LEP-layer 4.

The light emitting polymer layer 4 is of a first thickness 41 in a first domain 11 and of a second thickness 42 in a second domain 12 of the device.

The anode 2 and the cathode 5 are connected to a LED-driving unit 6, which drives the anode and the cathode such that domains of the device, corresponding to different domains of the patterned light emitting polymer layer 4, may be driven independently to emit light. The patterning of the light emitting layer into domains and the independent driving of those domains gives that the device is patterned into a plurality of different domains 11, 12.

When driven at the same voltage, the different domains 11, 12 of the device emit light of different color-points, and thus, by driving the different domains independently, the total color emitted by the device may be tuned in a range defined by the color-points for the individual domains of the device.

As used herein, the term “color-point” refers to a certain coordinate in a chromaticity diagram, for example a (x,y)-coordinate in the 1931 CIE standard diagram or (u′,v′)-coordinate in the 1976 CIE standard diagram.

As used herein, the term “white light” refers to light having a color point inside the area of “white” light as defined in, for example, the 1931 or 1976 CIE standard diagram.

As used herein, the term “OLED” refers to all light emitting diodes (LEDs) based on organic electroluminescent compounds, such as light emitting materials based on electroluminescent small organic molecules (smOLED), polymers (polyLED), oligomers and dendrimers. Examples of suitable substrates include, but are not limited to glass and transparent plastic substrates. Plastic substrates are attractive alternatives when suitable, because they are lightweight, inexpensive and flexible, among other advantages. The anode is arranged on the substrate and may be of any suitable material known to those skilled in the art, such as indium tin oxide (ITO).

Typically, the light emitted by the light emitting polymer layer leaves the device via the anode side. Thus, the anode is preferably transparent or translucent. A hole-transporting and injecting buffer layer is arranged on the anode to transport holes (positive charges) towards and injecting holes into the light emitting layer under the influence of an electric field applied between the anode and the cathode.

Suitable hole transporting and injecting buffer layers for use in the present invention include, but are not limited to PEDOT:PSS (polyethylenedioxythiophene polystyrenesulfonate salt) and PANI (polyaniline). Other hole-transporting buffer materials, suitable for use in a device of the present invention, are known to those skilled in the art.

The hole transporting and injecting buffer layer is optional and may or may not be comprised in a device of the present invention. However, it is typically used as it improves the functionality of commonly used OLED-devices.

A device of the present invention may further in some embodiments comprise an electron transporting and injecting buffer layer, located between the cathode and the light emitting layer, as such layers in some embodiments may improve the functionality of the device.

Examples of suitable materials having electron injecting and/or transporting functionality includes, but are not limited to TPBI: 2,2′,2″-(1,3,5-benzenetriyl)tris[1-phenyl-1H-benzimidazole], DCP: 2,9 dimethyl-4,7-diphenyl-phenantroline, TAZ: 3-phenyl-4-(1′naphtyl)-5-phenyl-1,2,4-triazole and OXD7: 1,3-bis(N,N-t-butyl-phenyl)-1,3,4-oxadiazole. More examples of such materials are described in Adv. Mater. 16 (2004) 1585-1595 and Appl. Phys. Lett. (2002) 1738-1740.

A device of the present invention may also comprise other additional layers with optical and/or electrical functionality, as is known to those skilled in the art. The light emitting layer may comprise any organic electroluminescent light emitting compound or combinations of such compounds known to those skilled in the art. Light of virtually every color is possible to achieve by such organic electroluminescent compounds. Examples of organic electroluminescent compounds include electroluminescent small organic molecules, oligomers, polymers and dendrimers.

Examples include, but are not limited to Alq3: tris(8-hydroxy-quinoline)aluminium and Ir(py)3: tris(2-phenylpyridine)iridium. More examples are described in for example Adv. Mater. 16 (2004) 1585-1595 and Appl. Phys. Lett. (2002) 1738-1740.

Conventional electroluminescent polymers include organic material such as derivatives of poly(p-phenylene vinylene) (PPV) or polyfluorenes and poly(spiro-fluorenes). Other electroluminescent polymers are well known to those skilled in the art.

Any electroluminescent polymer or combination of such polymers may be used in a light emitting polymer layer of the present invention to obtain any desired color. For example, essentially white light may be obtained by a blended combination of a blue-emitting polymer and a red-emitting polymer. One example of such a combination will be described in the following examples. Other combinations of light emitting polymers for providing light of different colors are known to those skilled in the art, as well as single component polymers incorporating different dye monomers on one polymer chain.

The light emitting layer in the embodiment shown in FIG. 1 is patterned into domains of two different thicknesses. However, as will be apparent to those skilled in the art, the light emitting layer may also be patterned into domains of more than two different thicknesses, such as a third domain of a third thickness and a fourth domain of a fourth thickness. The more thicknesses available, the more fine-tuning is allowed in the device.

A number of techniques for forming the light emitting layer with patterned thickness are contemplated as possible. For example, the light emitting layer may be deposited by ink-jet printing of the material on the hole transporting buffer layer, to control the amount of material deposited in, and thus the thickness of the material of an area. Other techniques include use of a retractable shadow mask when evaporation is used to deposit material(s), and molding as discussed in e.g. U.S. Pat. No. 6,252,253.

The light emitting layer may independently vary in thickness in different domains. The light emitting layer may have any thickness at which the light emitting layer is capable of emitting light under the influence of an electrical field, and will be different for different types of devices, where the minimum thickness in some smOLED devices is of the order of 10 nm, and the maximum in LEEC-devices in of the order of 500 nm.

The above description relates to a single light emitting layer. However, in some embodiments the light emitting layer may comprise more than one, such as for example two or three, separate sub-layers arranged on top of each other. For example, a blue-emitting layer may be arranged on top of an orange-emitting layer in order to provide white light. In such an embodiment, the thickness of one or more of such sub-layers may be patterned in thickness to provide a device of the present invention.

The above description mentions mostly electroluminescent polymers. However, the present invention also relates to other light emitting materials based on organic electroluminescent compounds, such as electroluminescent small organic molecules, oligomers and dendrimers. As will be apparent to those skilled in the art, also different combinations of such organic electroluminescent compounds may be useful in a device of the present invention. The cathode is arranged on the light emitting layer, optionally with an electron transporting and injecting layer being sandwiched between the light emitting layer and the cathode, as described above. Several cathode materials are well known to those skilled in the art, and all of them are contemplated as suitable. Examples of suitable cathode materials include calcium, barium, lithium fluoride, magnesium and aluminum.

Typically, a device of the present invention is arranged such that light emitted by the light emitting layer leaves the device via the anode. However, in some embodiments of the present invention, light may also leave the device via the cathode layer. Thus, in such embodiments, the cathode may be formed by a material that is transparent or translucent to the emitted light. In a device of the present invention, the anode and the cathode are arranged such that the different domains of the device, corresponding to different domains of the patterned light emitting layer, are possible to drive independently.

As used herein “independently addressable domains” refers to that a domain is possible to drive, i.e. it is possible to apply an electrical field over a domain, irrespective of the driving of an adjacent domain.

It will be apparent to those skilled in the art how to arrange the anode and the cathode layers in order to obtain a domain-specific driving, and both active and passive driving of a device of the present invention may be suitable.

Thus, the color point of the total light emitted by a device of the present invention may be varied by mixing light from different domains of the device having different individual color points.

The above description of preferred embodiments are illustrative only, and modifications to and variants of these embodiments will be apparent to those skilled in the art. Such modifications and variants are also included within the scope of the appended claims. For example, it has been shown, see example 2 below, that the color point of light emitted by a device of the present invention is dependent of the voltage that drives the device. This effect could be combined with the color-effect of varying the thickness of layer, as described above, to obtain a color variable light emitting device.

In one embodiment of the present invention, the plurality of independently addressable domains are arranged on a single substrate, forming a single multi-domain LED-device.

In another embodiment of the present invention the different independently addressable domains are arranged on different substrates, forming a multi-LED-device.

### EXAMPLES

### Example 1

### Different LEP-Layer Thicknesses Lead to Different Color Points

Three polyLED-devices were manufactured, which were identical except for the LEP-layer thickness, which were 55 nm, 84 nm and 124 nm thick, respectively. A 205 nm, 200 nm and 206 nm thick layer of PEDOT:PSS, respectively, was used in the three devices as hole transport layer. The light emitting polymer (LEP) consisted of a mixture of 99% of blue emitting polymer (blue 1, formula I) and 1% of a red emitting polymer (NRS—PPV, formula II)

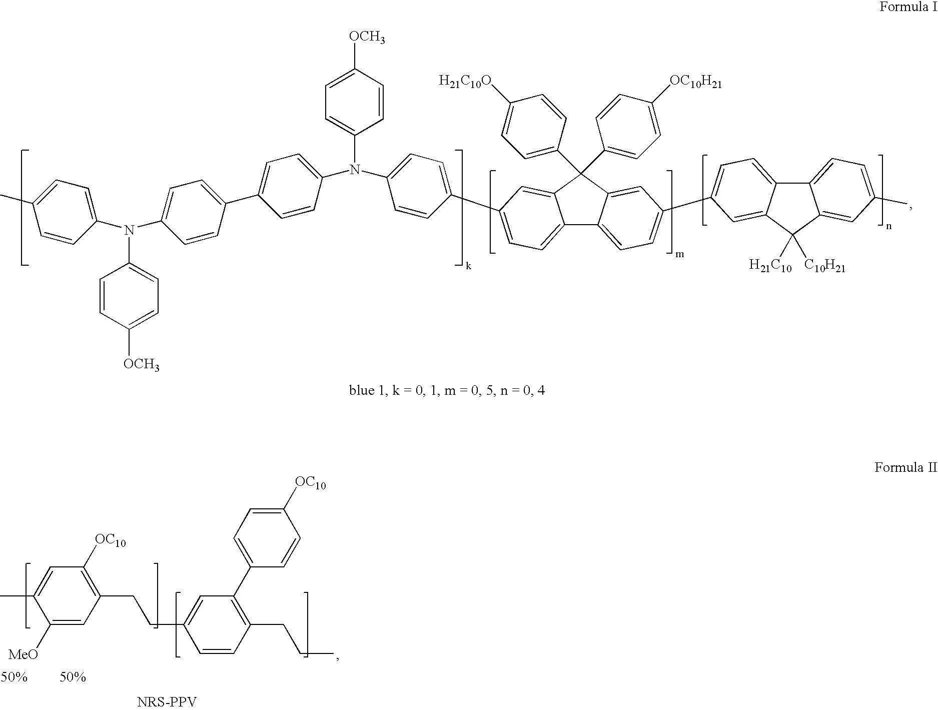

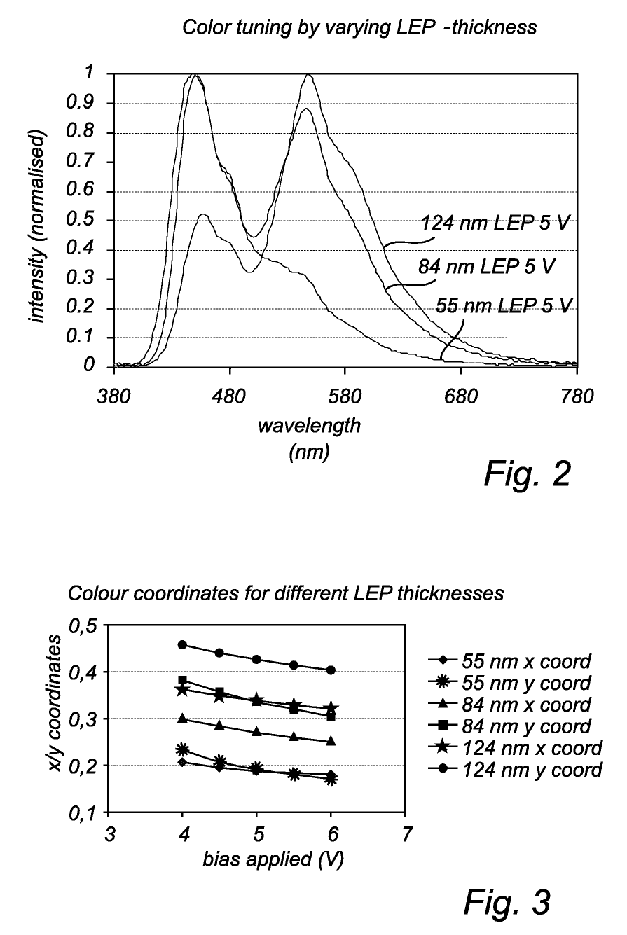

The spectra from the three different devices were compared at a bias of 5 Volts, and the results show clearly that an increase in LEP-layer thickness leads to an increase, both in x- and y-coordinate (FIGS. 2 and 3).

### Example 2

### Different Voltages Lead to Different Color Points

The three devices from example 1 were used and the color points of the emitted light were analyzed when the devices were driven at different voltages at 4, 4, 5, 5, 5, 5 and 6 Volts.

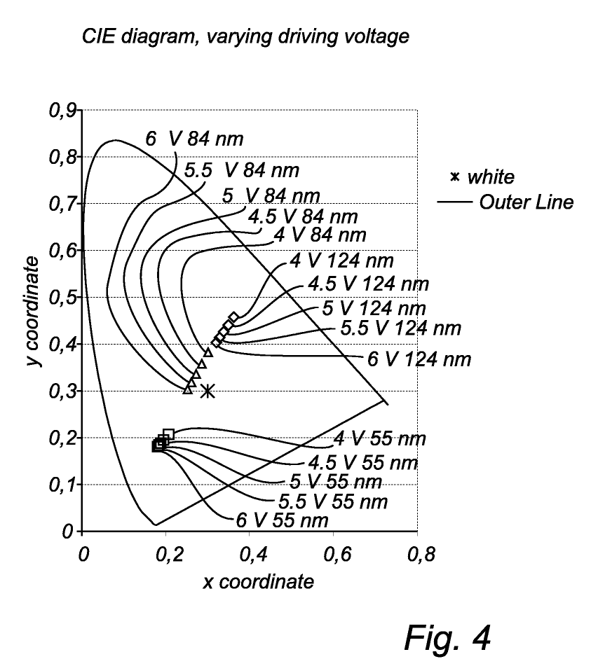

The results clearly show that the color coordinates decreases with increasing voltages, both in x- and y-coordinate (FIGS. 3 and 4). As shown in example 1 and 2, the color point of light emitted by the device depends on the thickness of the light emitting polymer layer.

Not wishing to be bound by any specific theory, different effects may account for this change of the color points.

One aspect of the tuning is the degree of quenching of the excited state in the presence of an electric field or charge carriers. The blue and the red emitting components of the polymer blend show a different degree of quenching owing to a difference in exciton binding energy, leading to a voltage-dependent color point. To a first approximation, the quenching scales with field applied or charge carrier concentration. Both field and charge carrier concentration do not scale linearly with current density or luminance when the thickness is varied, which creates an opportunity to tune quenching, and therefore, color point, independently from the luminance.

A second aspect of the tuning mechanism is the relative formation rate of excitons on the blue and red emitting components of the LEP-blend. Certain saturation or carrier mobility effects may occur when the carrier concentration is increased, shifting the balance of charge carrier concentration on either component, and thereby changing the ratio of blue and yellow light emission. Again, these saturation or mobility effects do not scale linearly with current or field when the thickness is varied, creating the possibility to achieve different colors points at the same luminance by variation of the thickness.

A third aspect of colors tuning is related to optical out-coupling. The exact position of the exciton, in particular the distance to anode and cathode, determines the colors of the light emission. Obviously, variation of the polymer film thickness leads to changes therein.

The above description of preferred embodiments and examples are illustrative only, and modifications to and variants of these embodiments will be apparent to those skilled in the art. Such modifications and variants are also included within the scope of the appended claims.

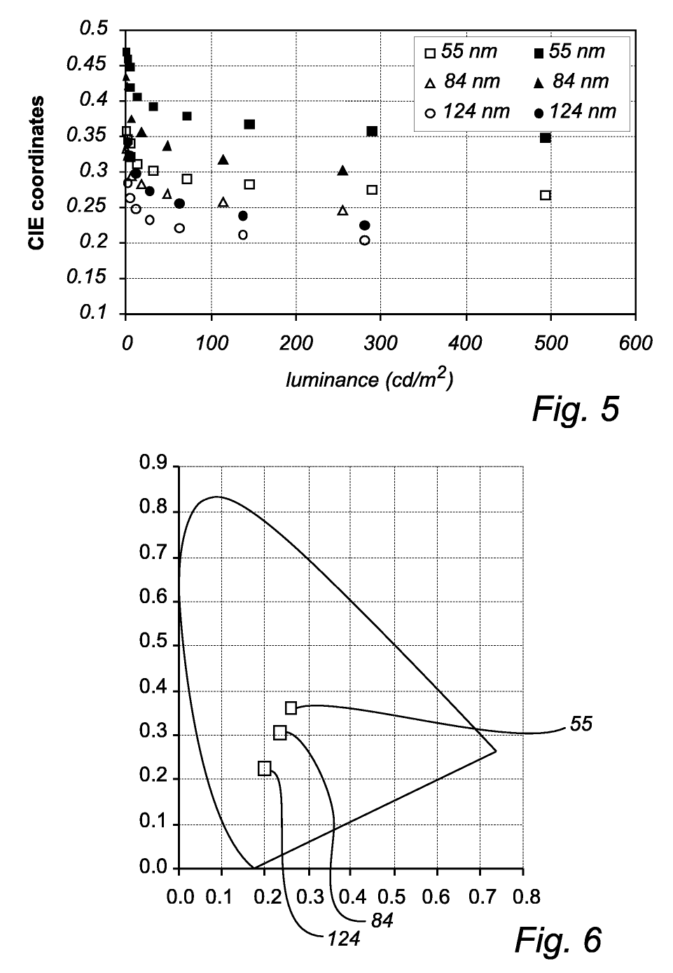

Example 1 and Example 2 showed color point variation as a function of thickness and voltage. However, these parameters also affect the luminance (‘brightness’) of the emitted light. In FIG. 5 the (x,y) CIE coordinates are plotted as a function of luminance for the three devices with different LEP-thickness in example 1. It is evident that meaningful variation of the color point may be achieved in an interesting luminance range. FIG. 6 plots the CIE-coordinates at 300 cd/m² (nit) for the different layer thicknesses of the three devices in example 1 and 2.

The color variation is similar in scope as a variation of the white point from 4,000 K to 10,000 K. This fits nicely into the range of white CIE coordinates used for lighting. Moreover, the thickness range used is of practical use. The efficiency does not drop to very low values, which would lead to high power consumption, and the voltage required is not extreme.

A practical implementation would be to have three types of pixels with the thickness shown in the graphs. By appropriate driving all colors between the extremes in FIG. 6 may then be generated. For example, 100 nit (0.20;0.22) would need 300 nit driving of the 55 nm pixel, in case of equal surface area of each thickness.

It should be noted that the thickness dependence of the color point in the luminance range from 100-1,000 nits is significantly larger than the voltage dependence in that same luminance range. Therefore, 300 nit (0.20;0.22) may also be generated by driving the 55 nm pixel at 900 nit. Thus, the combination of driving current and thickness dependence allows meaningful color tuning in an interesting luminance range.

White, or essentially white light may be advantageously emitted by a device of the present invention in several applications. However, the present invention is in no way limited to devices emitting white light, and devices providing tunable light of other colors may also be obtained, for example by utilizing electroluminescent compounds producing light of other colors.

1. A light emitting device comprising a substrate supporting an anode, a cathode and a light emitting layer comprising at least one organic electroluminescent compound, said light emitting layer being arranged between said anode and said cathode, and said device being patterned into a plurality of independently addressable domains, characterized in that
said light emitting layer is of a first thickness in a first domain of said device and of a second thickness in a second domain of said device, such that when a voltage, that is sufficient to cause light to emit from said first domain and said second domain, is applied over said light emitting layer, light of a first color point is emitted by said first domain of said device and light of a second color point is emitted by said second domain of said device.

2. A device according to claim 1, wherein said light emitting layer comprises a combination of at least a first organic electroluminescent compound and a second organic electroluminescent compound.

3. A device according to claim 1, wherein said first and/or second organic electroluminescent compound comprises an electroluminescent polymer.

4. A device according to claim 1, wherein said first color point represents a first white color point and said second color point represents a second white color point.

5. A device according to claim 1, comprising at least a second light emitting layer being arranged between said anode and said cathode.

6. A device according to claim 1, comprising at least one layer, having hole transporting and/or hole injecting functionality, being arranged between said light emitting layer and said anode.

7. A device according to claim 1, comprising at least one layer having electron transporting and/or electron injecting functionality, being arranged between said light emitting layer and said cathode.

8. A lighting system comprising a device according to claim 1.

9. A display device comprising a device according to claim 1.
